(19) United States
(12) Patent Application Publication
(10) Pub. No.: US 2014/0097540 A1
(43) Pub. Date: Apr. 10, 2014

(54) SEMICONDUCTOR STRUCTURE

(71) Applicant: CHIPBOND TECHNOLOGY CORPORATION, Hsinchu (TW)

(72) Inventors: Hsiang-Chin Chiu, Hsinchu County (TW); Sheng-Ming Wu, Hualien County (TW); Kuang-Hao Yang, Taichung City (TW); Kung-An Lin, Hsinchu City (TW); Chen-Yu Wang, Hsinchu City (TW)

(73) Assignee: CHIPBOND TECHNOLOGY CORPORATION, Hsinchu (TW)

(21) Appl. No.: 13/677,518

(22) Filed: Nov. 15, 2012

(30) Foreign Application Priority Data
Oct. 5, 2012 (TW) 101136960

(51) Int. Cl. H01L 23/373; H01L 23/482

(52) U.S. Cl. CPC H01L 23/3735; H01L 23/4827
USPC 257/753

(57) ABSTRACT

A semiconductor structure includes a silicon substrate, a titanium layer, a nickel layer, a silver layer and a metallic adhesion layer, wherein the silicon substrate comprises a back surface, and the titanium layer comprises an upper surface. The titanium layer is formed on the back surface, the nickel layer is formed on the upper surface, the silver layer is formed on the nickel layer, and the metallic adhesion layer is formed between the nickel layer and the silver layer.

### FIELD OF THE INVENTION

The present invention is generally related to a semiconductor structure, which particularly relates to the semiconductor structure with low resistance.

### BACKGROUND OF THE INVENTION

In conventional semiconductor process, a back side metal process is developed in order to improve heat dissipation of high power IC, which evaporates or sputters one single metallic layer or multiple metallic layers on back side of a wafer for purpose of connection or heat conduction. Besides, mentioned metallic layer further connects to a base material (e.g. lead frame) for achieving a better heat dissipation or electrical conductivity. Generally, the material of the metallic layer evaporated or sputtered on back side of the wafer is selected from one of gold or silver. Since gold values at a higher price than silver, hence silver is considered a better choice based on cost estimation. However, a titanium layer acted as an adhesion layer is necessarily connected between a silver layer and a silicon wafer. Under situations of overheating as well as thin titanium layer in the back end package process, the silver layer is likely melted and spreads toward the titanium layer and the silicon wafer therefore leading a separation between the silver layer and the silicon wafer. Oppositely, under situations of overheating as well as thick titanium layer in the back end package process, an inter-metallic compound will be produced between the titanium layer and the silver layer therefore resulting higher resistance.

### SUMMARY

The primary object of the present invention is to provide a semiconductor structure including a silicon substrate, a titanium layer, a nickel layer, a silver layer and a metallic adhesion layer. The silicon substrate comprises an active surface and a back surface, the titanium layer comprises an upper surface, the titanium layer is formed on the back surface, and the nickel layer is formed on the upper surface of the titanium layer. The silver layer is formed on the nickel layer, and the metallic adhesion layer is formed between the nickel layer and the silver layer. A good coupling strength between the nickel layer and the silver layer is obtainable by means of the metallic adhesion layer. Further, the nickel layer acts as a good barrier layer so that the semiconductor structure possesses the best heat dissipation and electrical conductivity, and the resistance of the semiconductor structure after packaging is well reduced.

### DESCRIPTION OF THE DRAWINGS

FIG. 1 is a schematic diagram illustrating a semiconductor structure in accordance with a preferred embodiment of the present invention.

FIG. 2 is an SEM photo illustrating a semiconductor structure in accordance with a preferred embodiment of the present invention.

### DETAILED DESCRIPTION OF THE INVENTION

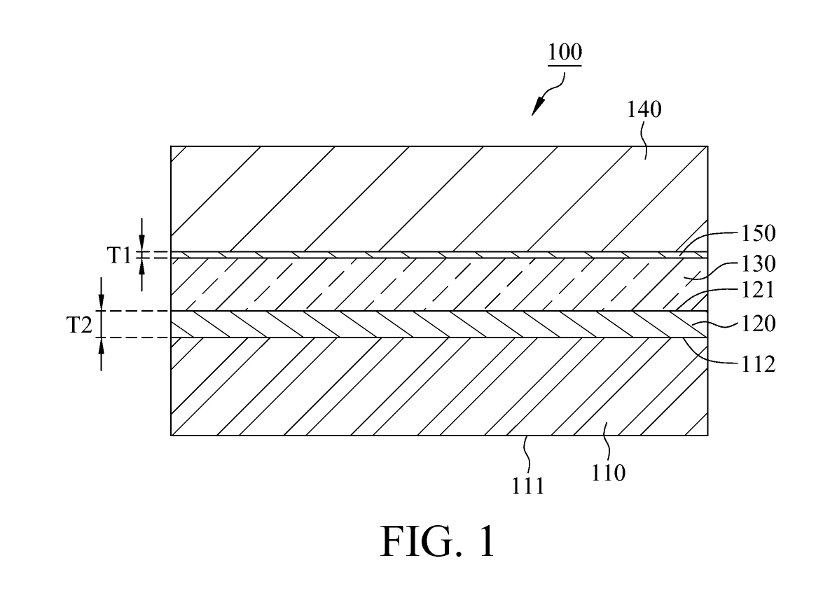

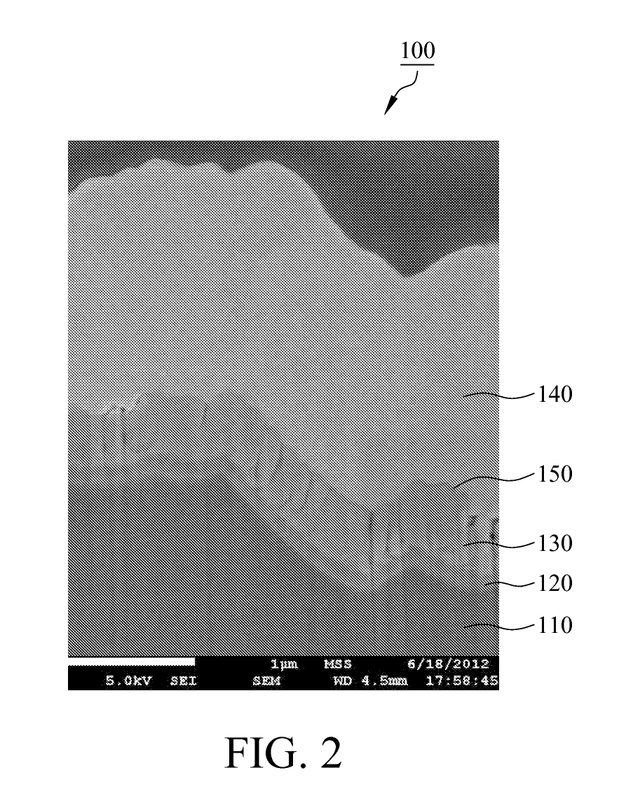

With reference to FIGS. 1 and 2, a semiconductor structure 100 in accordance with a preferred embodiment of the present invention includes a silicon substrate 110, a titanium layer 120, a nickel layer 130, a silver layer 140 and a metallic adhesion layer 150. The silicon substrate 110 comprises an active surface 111 and a back surface 112, wherein a plurality of traces and a plurality of connection devices (not shown in Figs.) are formed on the active surface 111, and the titanium layer 120 is formed on the back surface 112. The titanium layer 120 comprises an upper surface 121, and the thickness of the titanium layer 120 ranges from 100-10000 Å. Prior to a step of forming the titanium layer 120 on the back surface 112 of the silicon substrate 110, some steps must proceed in advance: firstly, disposing a protection tape (not shown in Figs.) on the active surface 111 of the silicon substrate 110; next, grinding the back surface 112 of the silicon substrate 110 for thinning the silicon substrate 110; thereafter, etching the back surface 112 of the silicon substrate 110 to increase roughness of the back surface 112 therefore raising the coupling strength between the titanium layer 120 and the silicon substrate 110; after that, making the titanium layer 120 formed on the back surface 112 of the silicon substrate 110 by means of evaporation or sputtering. The nickel layer 130 is formed on the upper surface 121 of the titanium layer 120, and the thickness of the nickel layer 130 ranges from 100-10000 Å. The silver layer 140 is formed on the nickel layer 130, and the thickness of the silver layer 140 ranges from 100-100000 Å. The metallic adhesion layer 150 is formed between the nickel layer 130 and the silver layer 140. In this embodiment, the material of the metallic adhesion layer 150 is titanium, the thickness of the metallic adhesion layer 150 ranges from 1-5000 Å, the metallic adhesion layer 150 comprises a first thickness T1, the titanium layer 120 comprises a second thickness T2, and the first thickness T1 is not bigger than the second thickness T2. Titanium is considered a good adhesion for metallic materials. Therefore, the material of the metallic adhesion layer 150 is titanium, and the thickness of metallic adhesion layer 150 ranges from 1-5000 Å. The good coupling strength between the nickel layer 130 and the silver layer 140 in the semiconductor structure 100 is achieved via the metallic adhesion layer 150. In addition, an inter-metallic compound will not be produced between the metallic adhesion layer 150 and the silver layer 140. Besides, the nickel layer 130 acts as a good barrier layer owning to the nickel layer 130 located between the silver layer 140 and the titanium layer 120 so that the best heat dissipation and electrical conductivity of the semiconductor structure 100 is obtainable, and the resistance of the semiconductor structure 100 after packaging is well reduced.

While this invention has been particularly illustrated and described in detail with respect to the preferred embodiments thereof, it will be clearly understood by those skilled in the art that it is not limited to the specific features and describes and various modifications and changes in form and details may be made without departing from the spirit and scope of this invention.

1. A semiconductor structure at least includes:
a silicon substrate having an active surface and a back surface;
a titanium layer formed on the back surface comprises an upper surface;
a nickel layer formed on the upper surface of the titanium layer;
a silver layer formed on the nickel layer; and
a metallic adhesion layer formed between the nickel layer and the silver layer, wherein the metallic adhesion layer comprises a first thickness and the titanium layer comprises a second thickness such that the first thickness is not greater than the second thickness.

2. The semiconductor structure in accordance with claim 1, wherein the material of the metallic adhesive layer is titanium.

3. The semiconductor structure in accordance with claim 1, wherein the thickness of the titanium layer ranges from 100-10000 Å.

4. The semiconductor structure in accordance with claim 1, wherein the thickness of the nickel layer ranges from 100-10000 Å.

5. The semiconductor structure in accordance with claim 1, wherein the thickness of the silver layer ranges from 100-100000 Å.

6. The semiconductor structure in accordance with claim 1, wherein the thickness of the metallic adhesion layer ranges from 1-5000 Å.

7. (canceled)
